(19) United States
(12) Patent Application Publication
(10) Pub. No.: US 2008/0049275 A1
(43) Pub. Date: Feb. 28, 2008

(54) Image adjusting device

(75) Inventors: Kai-Hsiang Hsu, Tucheng City (TW); Yi-Chia Shan, Jhongli City (TW); Tsan-Hung Tsai, Sanchong City (TW); Hsu-Chia Kao, Pingjhen City (TW)

Correspondence Address: BIRCH STEWART KOLASCH & BIRCH, PO BOX 747, FALLS CHURCH, VA, 22040-0747, US

(73) Assignee: MARKETECH INTERNATIONAL CORP.

(21) Appl. No.: 11/730,369

(22) Filed: Mar. 30, 2007

(30) Foreign Application Priority Data
Aug. 23, 2006 (TW) 095130930

(51) Int. Cl. G03F 3/08

(52) U.S. Cl. 358/520

(57) ABSTRACT

The invention discloses an image adjusting device. According to a certain color axis and a certain adjusting parameter selected by a user, the image adjusting device is used for adjusting a current image parameter (such as lightness or saturation). The image adjusting device of the invention is capable of providing different adjusting gains for adjusting the lightness or the saturation based on different color axes, such that the image can be displayed smoothly without any uneven lines. Consequently, the image quality can be improved.

### BACKGROUND OF THE INVENTION

1. Field of the invention

The invention relates to an image adjusting device and, more particularly, to an image adjusting device which can adjust lightness or saturation respectively according to different color axes.

2. Description of the prior art

In general, the adjustable image parameters of an image comprise lightness, hue, and saturation. When adjusting the image, the image signal must be converted from the original color space (e.g. RGB) to the color space (e.g. YCbCr, YUV, CELab, etc.) where the lightness (Y) and the colors (C) are separated. Then, the information about the lightness, the hue, and the saturation of the image can be obtained. Referring to FIG. 1, FIG. 1 is a schematic diagram of Lab color space. Taking the Lab color space for example, L represents lightness component; a and b represent color components. As shown in FIG. 1, in the Lab color space, the lightness (L) is controlled by a height, the hue (H) is controlled by an angle, and the saturation (S) is controlled by a radius.

The distribution of the hue ranges from 0° to 360° in the Y/C separated color space. Besides, the distribution of the hue can be divided into several color axes with different range of the angle according to the practical requirement. Referring to FIG. 2, FIG. 2 is a schematic diagram of the hue divided into six color axes according to the prior art. In the prior art, the conventional integrated circuit (IC) used to adjust color often divides colors into six color axes according to their hues. As shown in FIG. 2, these color axes are red (R), blue (B), green (G), cyan (C), magenta (M), and yellow (Y) respectively. Furthermore, the color of skin may be added to those color axes by some ICs. Thus, it is convenient for the user to adjust when there are seven color axes in total.

Referring to FIG. 3 and FIG. 4, FIG. 3 is a schematic diagram of selecting color axis and adjusting image parameter. And, FIG. 4 is a schematic diagram of the same gain corresponding to a certain axis. As shown in FIG. 3, the user can use the on screen display (OSD) to select the axis to be adjusted first; then, he/she can select the image parameter to be adjusted (e.g. lightness, hue, or saturation) later. In the prior art, after the axis is selected, the lightness or saturation of all pixels comprised in the axis is adjusted by the same gain, as shown in FIG. 4. However, this will make the adjusted image appear uneven lines (color difference). In order to achieve better adjusting effects, when adjusting lightness or saturation, each of the color axes must be independent to each other; and, the set-up value of each color axis and each hue angle should be different. Based upon these, the adjusted image will not appear uneven lines (color difference).

Therefore, the main scope of the invention is to provide an image adjusting device which can respectively adjust lightness or saturation according to different axes.

### SUMMARY OF THE INVENTION

A scope of the invention is to provide an image adjusting device which can provide different adjusting values to adjust lightness or saturation according to various color axes and hue angles, and it can make the adjusted image on the screen smoother and further enhance the quality of the image.

According to a preferred embodiment of the invention, the image adjusting device is applied to adjust the current image parameter of a pixel of an image signal according to a user-selected color axis and a user-selected adjusting parameter in a display system. In the display system, the pixel of the image signal is converted to the one that comprises a lightness component, a first color component, and a second color component. And, the image adjusting device comprises a first processing unit, a second processing unit, a third processing unit, and a calculating unit.

In the above embodiment, the first processing unit is used to provide a corresponding adjusting value according to the user-selected color axis and the user-selected adjusting parameter. The second processing unit stores a first look-up table, and the first look-up table records a plurality of gains. In the first look-up table, each of the gains is corresponding to at least one image parameter (e.g. lightness, hue, and/or saturation). The second processing unit also decides a corresponding gain according to the first look-up table and the lightness, hue, and/or saturation of the pixel of the input image. And, the calculating unit is used to calculate an adjusting gain according to the corresponding adjusting value and the corresponding gain.

When the image adjusting device of the invention is used to adjust the lightness of the pixel of the image signal, the third processing unit is used to multiply the lightness of the pixel of the image signal by the adjusting gain. In this way, the lightness of the pixel of the image signal has been adjusted.

When the image adjusting device of the invention is used to adjust the saturation of the pixel of the image signal, the third processing unit is used to multiply the first color component and the second color component of the pixel of the image signal by the adjusting gain respectively. By doing so, the saturation of the pixel of the image signal has been adjusted.

Therefore, the image adjusting device of the invention is capable of providing different adjusting gains for adjusting the lightness or the saturation based on different color axes, such that the image can be displayed smoothly and the image quality can be further improved.

The advantage and spirit of the invention may be understood by the following recitations together with the appended drawings.

### BRIEF DESCRIPTION OF THE APPENDED DRAWINGS

FIG. 1 is a schematic diagram of the Lab color space.

FIG. 2 is a schematic diagram of the hue being divided into six color axes according to the prior art.

FIG. 3 is a schematic diagram of selecting color axis and adjusting image parameter.

FIG. 4 is a schematic diagram of the same gain corresponding to certain axis.

FIG. 5 is a functional block diagram of a display system 1 according to a preferred embodiment of the invention.

FIG. 6 is a schematic diagram of selecting the color axis and adjusting the image state.

FIG. 7 is a functional block diagram of the lightness adjusting device shown in FIG. 5.

FIG. 8A is a schematic diagram of the second look-up table shown in FIG. 7.

FIG. 8B is a schematic diagram of the second color axis shown in FIG. 8A.

FIG. 9A is a schematic diagram of the first look-up table shown in FIG. 7.

FIG. 9B is a schematic diagram of the first look-up table according to another preferred embodiment of the invention.

FIG. 10 is a functional block diagram of the saturation adjusting device shown in FIG. 5.

FIG. 11 is a schematic diagram of different gains corresponding to certain color axis.

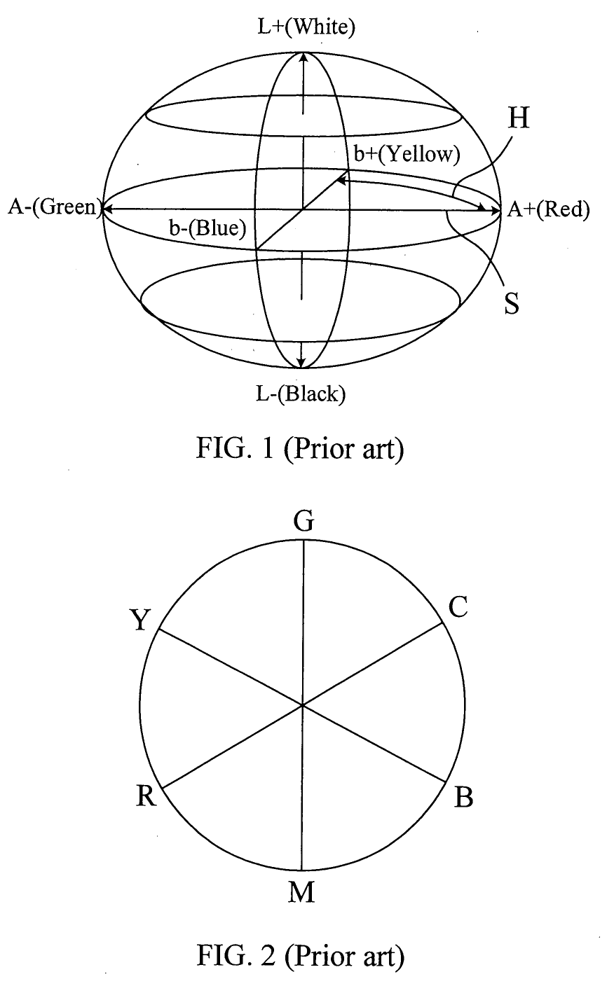

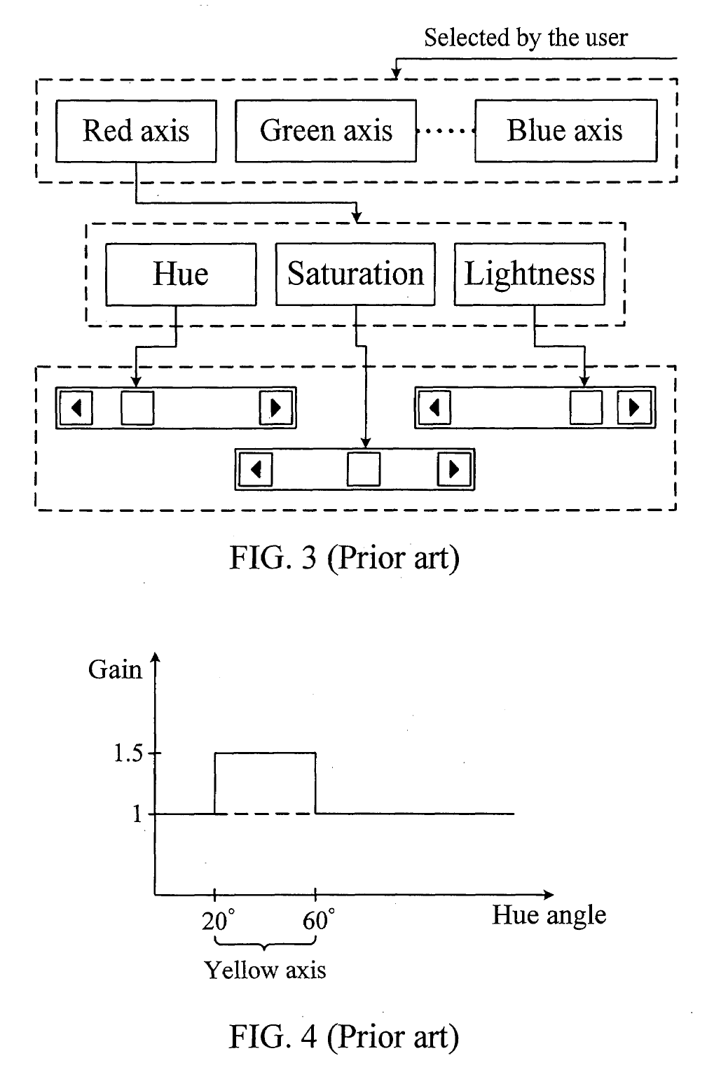

### DETAILED DESCRIPTION OF THE INVENTION

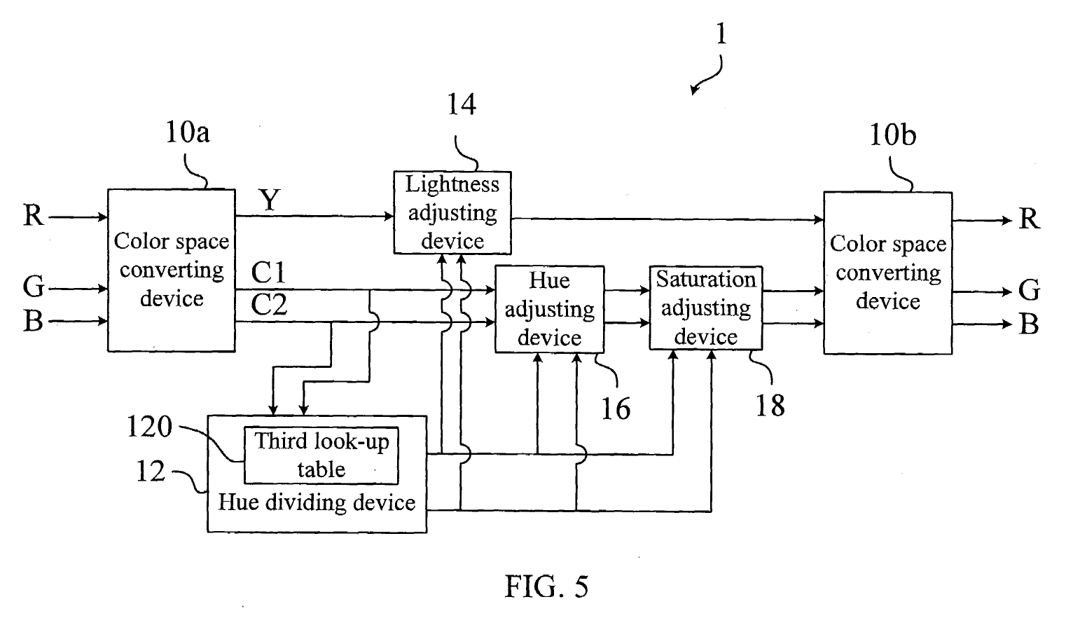

Referring to FIG. 5, FIG. 5 is a functional block diagram of a display system 1 according to a preferred embodiment of the invention. As shown in FIG. 5, the display system 1 comprises color space converting devices 10a, 10b, a hue dividing device 12, a lightness adjusting device 14, a hue adjusting device 16, and a saturation adjusting device 18.

The invention can be applied to all color spaces having lightness separated from colors, such as YCbCr, YUV, CIELab, etc. In this embodiment, the color space converting device 10a of the display system 1 will convert the image signal from the original color space (e.g. RGB) to the color space (e.g. CIELab) having lightness separated from colors. Then, the information about the lightness, the hue, and the saturation of the image can be further obtained. And, the distribution of the hue ranges from 0° to 360°. In other words, when the image signal composed of a plurality of pixels is inputted to the display system 1, each of the pixels of the image signal will be converted to the one that includes lightness component Y, first color component C1, and second color component C2. This can be easily achieved by one skilled in the art, so the details are not further described.

The hue dividing device 12 is used to divide the hue angles of the color space into a plurality of color axes. In this embodiment, the hue dividing device 12 stores a third look-up table 120, and the third look-up table 120 records a plurality of boundaries, with a view to divide the hue angles into a plurality of color axes. For example, the third look-up table 120 can record 17 boundaries which are set as 0, 22, 44, 66, 88, 110, 132, 154, 176, 198, 220, 242, 264, 286, 308, 330, 360 to further divide the hue angles into 16 axes. That is to say, the first color axis comprises hue angles ranging from 0° to 21°; the second color axis comprises hue angles ranging from 22° to 43°, and so forth.

In this embodiment, the image adjusting device of the invention is used to adjust the current image parameter (lightness) of a pixel of an image signal according to a user-selected color axis and a user-selected adjusting parameter in the display system 1. In other words, the lightness adjusting device 14 shown in FIG. 5 is the image adjusting device of the invention.

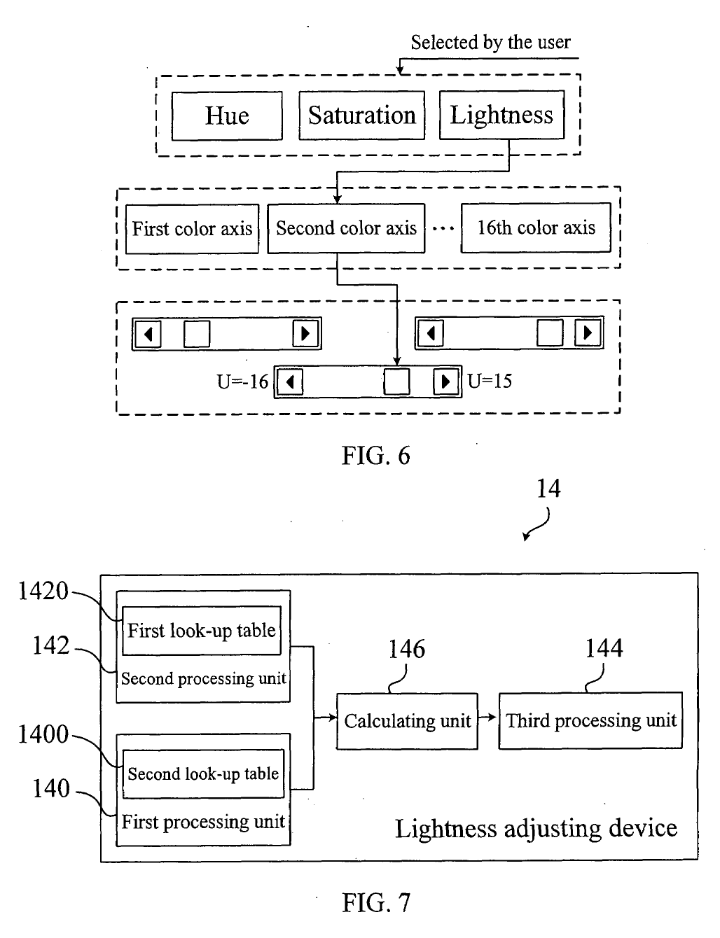

Referring to FIG. 6, FIG. 6 is a schematic diagram of selecting the color axis and adjusting the image state. The user can make an adjustment by selecting lightness with the on screen display (OSD) shown in FIG. 6. As shown in FIG. 6, the adjusting parameter U can be set as −16˜15, wherein the negative value represents “lowering the lightness” and the positive value represents “heightening the lightness”. Therefore, when adjusting the lightness, the user can first select the axis which is desirous to be adjusted, and then choose the parameter which is desirous to be adjusted.

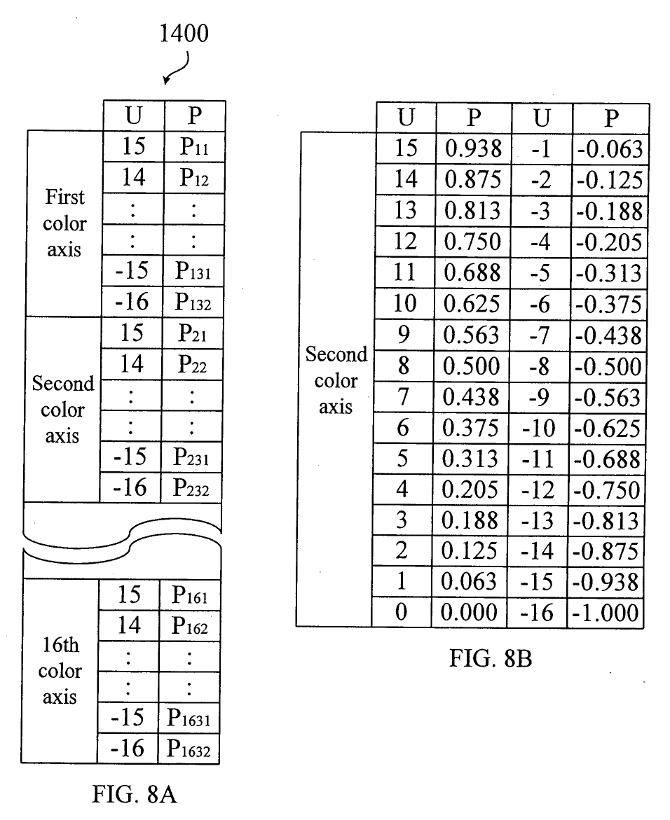

Referring to FIG. 7 to FIG. 8B, FIG. 7 is a functional block diagram of the lightness adjusting device 14 shown in FIG. 5. FIG. 8A is a schematic diagram of the second look-up table 1400 shown in FIG. 7. FIG. 8B is a schematic diagram of the second color axis shown in FIG. 8A. As shown in FIG. 7, the lightness adjusting device 14 comprises a first processing unit 140, a second processing unit 142, a third processing unit 144, and a calculating unit 146. The first processing unit 140 stores the second look-up table 1400. As shown in FIG. 8A, the second look-up table 1400 records 16 color axes. Each of the color axes is corresponding to 32 adjusting parameters and 32 adjusting values; each of the adjusting parameters is corresponding to one of the adjusting values. For example, the adjusting value corresponding to the second color axis can be set as shown in FIG. 8B. However, it should be noticed that the second look-up table 1400 shown in FIG. 8A can be designed differently according to the practical applications.

Besides, the adjusting value can also be calculated directly by the second processing unit 142. For example, if the adjusting value is set from −1 to 1 and there are 32 adjusting parameters, the adjusting value of the second look-up table will be calculated in proportion by the second processing unit 142 without storing the second look-up table 1400 separately.

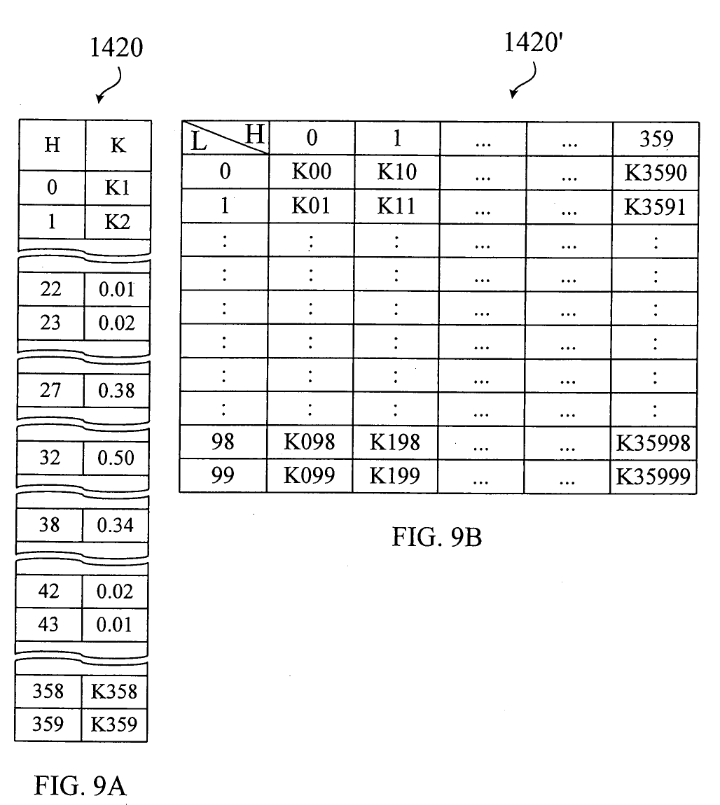

The second processing unit 142 stores the first look-up table 1420; the first look-up table 1420 records a plurality of gains; and each of the gains is corresponding to at least one image parameter (lightness, hue, and/or saturation). Referring to FIG. 9A and FIG. 9B, FIG. 9A is a schematic diagram of the first look-up table 1420 shown in FIG. 7. FIG. 9B is a schematic diagram of the first look-up table 1420′ according to another preferred embodiment of the invention. As shown in FIG. 9A, the first look-up table 1420 records 360 gains K, and each of the gains K is corresponding to the hue angles H respectively. As shown in FIG. 9B, each gain K of the first look-up table 1420′ is corresponding to the hue angles H and the lightness L respectively. In other words, the first look-up table 1420 shown in FIG. 9A can be diversely designed based on the practical applications.

For example, when the user-selected color axis is the second axis and the user-selected adjusting parameter is 7, the first processing unit 140 will provide the corresponding adjusting value 0.438 according to the second look-up table 1400. At the same time, the second processing unit 142 will decide the corresponding gain according to the first look-up table 1420 and the hue angle of the pixel of the input image. For example, if the hue angle of the pixel is 27°, the corresponding gain will be 0.38.

Afterward, the calculating unit 146 will calculate the adjusting gain G by the following formula 1 according to the corresponding adjusting value (P=0.438) and the corresponding gain (K=0.38):

G=1+P * K Formula 1

At last, the third processing unit 144 will multiply the lightness component Y of the pixel of the image signal by the adjusting gain G to generate the adjusted lightness Y_{adj} (that is, Y_{adj}=Y*G).

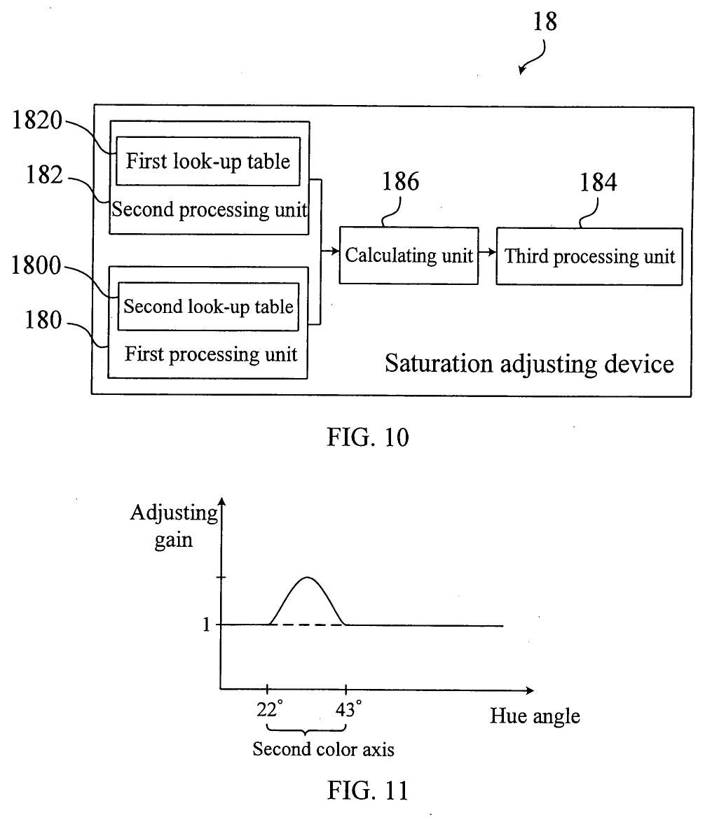

Referring to FIG. 10, FIG. 10 is a functional block diagram of the saturation adjusting device 18 shown in FIG. 5. The image adjusting device of the invention can also be used in the display system 1 to adjust the saturation of the pixel of the image signal according to the user-selected color axes and the user-selected adjusting parameters. In other words, the image adjusting device of the invention can also be applied to the saturation adjusting device 18. The main difference between the saturation adjusting device 18 and the lightness adjusting device 14 is that the third processing unit 184 of the saturation adjusting device 18 is used to adjust the saturation of the pixel of the image signal by the following formula 2:

C1_{adj}=C1* G; and C2_{adj}=C2* G; Formula 2

wherein C1_{adj} represents the adjusted first color component, and C2_{adj} represents the adjusted second color component. The adjusted saturation can be converted by C1_{adj} and C2_{adj}.

It should be noticed that the functional theorem of other components in the saturation adjusting device 18, such as the first processing unit 180, the second look-up table 1800, the second processing unit 182, the first look-up table 1820, and the calculating unit 186, is the same as the lightness adjusting device 14; therefore, the details are not further described.

Referring to FIG. 11, FIG. 11 is a schematic diagram of different gains corresponding to certain color axis. In order to achieve better adjusting effect, when adjusting lightness or saturation, not only each of the axes is independent to each other, but also the adjusting gains of the same color axis are totally different. Thus, the uneven lines (color difference) will not appear in the adjusted image.

Referring to FIG. 5 again, the hue of the input image can also be adjusted by the hue adjusting device 16. At last, the input image will be converted to the original color space (e.g., converted from the Lab color space to the RGB color space). The related techniques can be easily achieved by one skilled in the art, so the details are not further described.

Compared with the prior art, the image adjusting device of the invention is capable of providing different adjusting gains for adjusting the lightness or the saturation based on different color axes, such that the image can be displayed smoothly and the image quality can be further improved.

With the above example and explanation, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An image adjusting device, applied to a display system, for adjusting a current image parameter of a pixel of an image signal according to a user-selected color axis and a user-selected adjusting parameter, the image adjusting device comprising:
a first processing unit for providing a corresponding adjusting value according to the user-selected color axis and the user-selected adjusting parameter;
a second processing unit for storing a first look-up table, the first look-up table recording a plurality of gains, each of the gains being corresponding to at least one image parameter, the second processing unit determining a corresponding gain according to the first look-up table and the at least one image parameter of the pixel of the input image;
a calculating unit for calculating an adjusting gain according to the corresponding adjusting value and the corresponding gain; and
a third processing unit for multiplying the current image parameter of the pixel of the image signal by the adjusting gain.

2. The image adjusting device of claim 1, wherein the first processing unit stores a second look-up table, the second look-up table records a plurality of color axes, each of the color axes is corresponding to a plurality of adjusting parameters and a plurality of adjusting values respectively, each of the adjusting parameters is corresponding to one of the adjusting values respectively, the user-selected color axis is selected from one of the color axes, the user-selected adjusting parameter is selected from one of the adjusting parameters, and the corresponding adjusting value is selected from one of the adjusting values.

3. The image adjusting device of claim 1, wherein the at least one image parameter comprises lightness, hue, and/or saturation.

4. The image adjusting device of claim 1, wherein the adjusting gain G is calculated by the following formula:
G=1+P * K;
wherein P represents the corresponding adjusting value and K represents the corresponding gain.

5. The image adjusting device of claim 3, wherein the current image parameter is lightness of the pixel of the image signal.

6. The image adjusting device of claim 3, wherein the current image parameter is saturation of the pixel of the image signal.

7. The image adjusting device of claim 5, wherein the pixel of the image signal is converted to a pixel comprising a first color component C1 and a second color component C2, the saturation of the pixel of the image signal is adjusted by the following formula:
C1_{adj}=C1* G; and
C2_{adj}=C2* G;
wherein C1_{adj} represents the adjusted first color component, C2_{adj} represents the adjusted second color component.
